(19) United States
(12) Patent Application Publication
(10) Pub. No.: US 2009/0201748 A1
(43) Pub. Date: Aug. 13, 2009

(54) REMOVABLE NONVOLATILE MEMORY SYSTEM WITH DESTRUCTIVE READ

(75) Inventor: Yosuke Muraki, Campbell, CA (US)

Correspondence Address: LAW OFFICES OF MIKIO ISHIMARU, 333 W. EL CAMINO REAL, SUITE 330, SUNNYVALE, CA, 94087, US

(73) Assignees: SONY CORPORATION, Tokyo (JP); SONY ELECTRONICS INC., Park Ridge, NJ (US)

(21) Appl. No.: 12/028,965

(22) Filed: Feb. 11, 2008

(51) Int. Cl. G11C 7/00

(52) U.S. Cl. 365/189.14

(57) ABSTRACT

A removable nonvolatile memory system is provided including storing read data onto a memory portion of a memory device; and accessing the memory portion including reading the read data from the memory portion, and writing predetermined data onto the memory portion after reading the memory portion.

### TECHNICAL FIELD

The present invention relates generally to a memory system and more particularly to a removable nonvolatile memory system.

### BACKGROUND ART

In the connected world, people create, transport, store, and consume vast amount of information or data ranging from making a phone call, using the facsimile machine, and using the Internet to name a few. The technologies that keep people connected are ubiquitous and always available. Some of these technologies to transport vast amounts of data involve network systems, such as routers and switches. There are different types of network systems utilized across the Internet including local area network (LAN), storage area network (SAN), metropolitan area network (MAN), and wide area network (WAN). Network systems also provide various connectivity options, such as wired, wireless, electrical, or optical.

However, as vast and pervasive the connected world has become, so has the expectation availability, portability, and security of data. Whether data is created on a laptop, handheld device, downloaded, or transferred, data security is a quintessential as the electronics used in the creation, transportation, storage, and consumption of the data. Data may range from enterprise information to personal notes and pictures. Whatever the content, it is important to some users.

One particular area for data security is in the storage of nonvolatile memories. These memories may include magnetic hard disk drive and nonvolatile random access memories. The nonvolatile memories allow storage of data while providing portable without the need for a power supply, such as a battery. As valuable as the portability and non-volatility may be for data storage and transportation, it presents potential security risk.

For example, portable memory devices such as Memory Stick and USB memory have large memory capacity for people to store a various kinds of data on them and can be hand-delivered to others in business or personal situations when a file size is too large to be emailed. Here, some security problems can arise. It is likely that such a portable memory device can be lost. Important data can be in danger of being stolen by a third party. Even if the data is encrypted, sophisticated software may decrypt it. Even if the data was “erased” with software (such as “removed”), usually the data still remains electrically and can be recovered with software.

Thus, a need still remains for a memory system for improving data security for removable nonvolatile memories to be used with the electronic systems. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides a removable nonvolatile memory system including storing read data onto a memory portion of a memory device; and accessing the memory portion including reading the read data from the memory portion, and writing predetermined data onto the memory portion after reading the memory portion.

Certain embodiments of the invention have other aspects in addition to or in place of those mentioned or obvious from the above. The aspects will become apparent to those skilled in the art from a reading of the following detailed description when taken with reference to the accompanying drawings.

### BRIEF DESCRIPTION OF THE DRAWINGS

FIG. 1 is a schematic view of an electronic system with a removable nonvolatile memory system in an application example of an embodiment of the present invention;

FIG. 2 is a schematic view of the removable nonvolatile memory system in an embodiment of the present invention;

FIG. 3 is an illustrative view of the removable nonvolatile memory system in an addressing step;

FIG. 4 is an illustrative view of the removable nonvolatile memory system in a reading step;

FIG. 5 is an illustrative view of the removable nonvolatile memory system in writing step;

FIG. 6 is an illustrative view of the removable nonvolatile memory system in a further addressing step; and

FIG. 7 is a flow chart of a removable nonvolatile memory system for operation of the removable nonvolatile memory system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail. Likewise, the drawings showing embodiments of the system are semi-diagrammatic and not to scale and, particularly, some of the dimensions are for the clarity of presentation and are shown greatly exaggerated in the drawing FIGs. Generally, the invention can be operated in any orientation. In addition, where multiple embodiments are disclosed and described having some features in common, for clarity and ease of illustration, description, and comprehension thereof, similar and like features one to another will ordinarily be described with like reference numerals.

For expository purposes, the term “horizontal” as used herein is defined as a plane parallel to the plane or surface of the integrated circuit, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements. The term “system” as used herein means and refers to the method and to the apparatus of the present invention in accordance with the context in which the term is used.

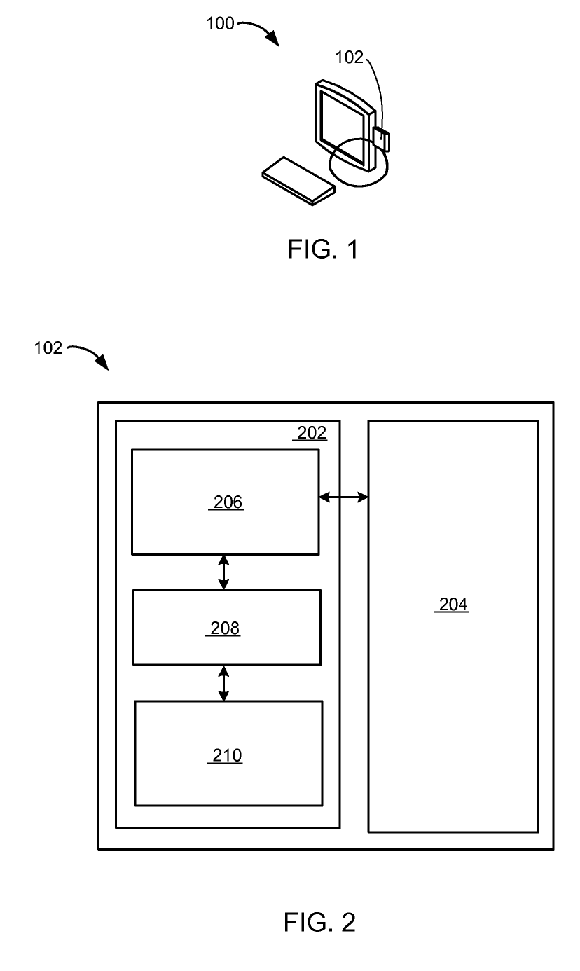

Referring now to FIG. 1, therein is shown a schematic view of an electronic system 100 with a removable nonvolatile memory system 102 in an application example of an embodiment of the present invention. The electronic system 100, such as desktop computer, may store data onto the removable nonvolatile memory system 102, such as removable hard drive or a nonvolatile memory stick. Also, the removable nonvolatile memory system 102 may also be inserted into the electronic system 100 to access the information from the removable nonvolatile memory system 102.

For illustrative purposes, the application of the removable nonvolatile memory system 102 is described as storing to and from the electronic system 100, although it is understood that the storage and reading of the data or information from the removable nonvolatile memory system 102 may be perform by another electronic system (not shown). For example, a smart phone (not shown) may store or read data that may be read or stored by, respectively, by the electronic system 100. The portability of the removable nonvolatile memory system 102 allows ease of storage, transport, and usage of data stored therein at other systems at different locations.

Referring now to FIG. 2, therein is shown a schematic view of the removable nonvolatile memory system 102 in an embodiment of the present invention. The removable nonvolatile memory system 102 includes a controller device 202 and a memory device 204. For example, the controller device 202 may be implemented as an integrated circuit device and the memory device 204 may be a nonvolatile memory device, nonvolatile random access memory device (NVRAM).

The controller device 202 can include an interface block 206, a data buffer block 208, and a control block 210. The interface block 206 can include functions, such as providing the appropriate communication signals and timing, for interfacing between the controller device 202 and the memory device 204. The data buffer block 208, such as an input first-in-first-out (FIFO) and an output first-in-first-out (FIFO), can store the data written to and read from the memory device 204 through the interface block 206. The control block 210 can provide the intelligence for operating the controller device 202 with the memory device 204. The control block 210 can control the read and write operation of the memory device 204. For example, the control block 210 can be implemented as a processor or processing core, a finite state machine, or a program state machine.

For illustrative purposes, the controller device 202 is shown with the interface block 206, the data buffer block 208, and the control block 210 as discrete functional blocks, although it is understood that the controller device 202 may be partitioned differently. For example, the controller device 202 may collapse the functions or some of the functions of the interface block 206, the data buffer block 208, and the control block 210 into the same block or partitioned into different blocks, such as the interface block 206 and the data buffer block 208 may be included into a single functional block.

Also for illustrative purposes, the controller device 202 is shown with the data buffer block 208 between the interface block 206 and the control block 210, also it is understood that the blocks in the controller device 202 may couple to each other differently. For example, the control block 210 may also couple with the interface block 206 without going through the data buffer block 208.

Further for illustrative purposes, the removable nonvolatile memory system 102 is shown with the controller device 202 and the memory device 204, although it is understood that the removable nonvolatile memory system 102 may include other circuits. For example, the removable nonvolatile memory system 102 may include passive devices, such as capacitor or resistors, or other external memory devices, such as a read only memory (ROM).

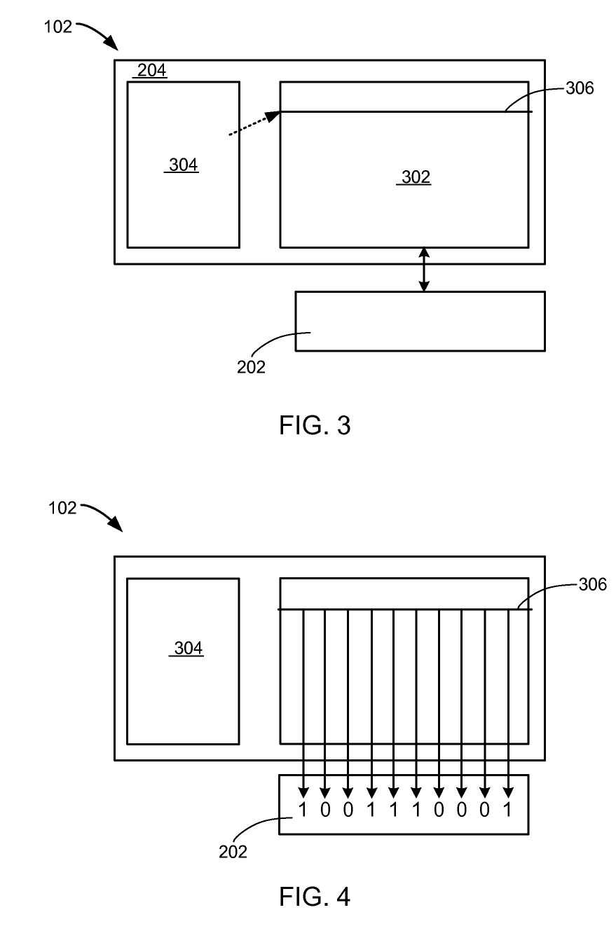

Referring now to FIG. 3, therein is shown an illustrative view of the removable nonvolatile memory system 102 in an addressing step. The illustrative view depicts the memory device 204 and the controller device 202. The memory device 204 can be organized as a memory array 302 and an address decoder 304. The address decoder 304 translates or decodes the address from the controller device 202 allowing access to a memory portion 306, such as a row, of the memory array 302. The memory portion 306 can be accessed for a read or write operation by the controller device 202.

The memory array 302 can be implemented with an array of nonvolatile memory cells. The address decoder 304 can be implemented with logic circuits, analog circuits, or a combination thereof.

For illustrative purposes, the memory device 204 is shown with the memory array 302 and the address decoder 304, although it is understood that the memory device 204 can be organized differently. For example, the memory device 204 can have multiple memory arrays with address decoders.

Referring now to FIG. 4, therein is shown an illustrative view of the removable nonvolatile memory system 102 in a reading step. The memory portion 306 can be read by the controller device 202 with the appropriate address sent to the address decoder 304. Data from the memory portion 306 addressed by the address decoder 304 is sent to the controller device 202.

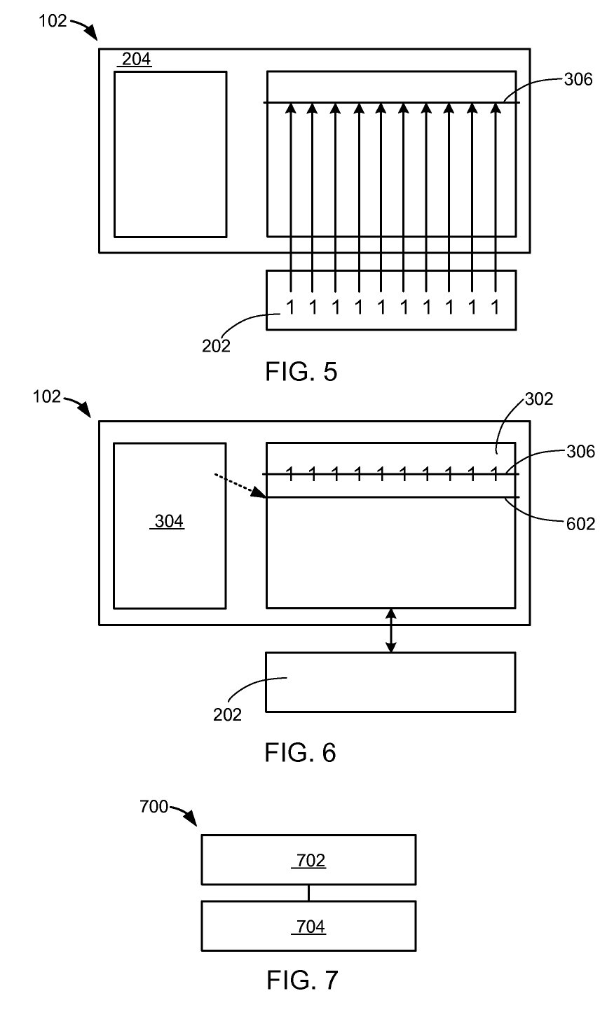

Referring now to FIG. 5, therein is shown an illustrative view of the removable nonvolatile memory system 102 in a writing step. The controller device 202 continues to access the memory portion 306 immediately after the read of the memory portion 306. This access allows the controller device 202 to immediately write to the memory portion 306 with a predetermined pattern following a read without an intervening write of other data. The predetermined data pattern is defined as all ones pattern, an alternating zero and one pattern, or a random zeros or ones pattern. The write of the memory portion 306 ensures that the data from the memory portion 306 can be read for a predetermined number of times, such as read once.

The write operation ensures that the data previously stored in the memory portion 306 is eliminated as opposed to a software erase operation. The software erase operation may leave the data available in the memory portion 306, which may be restored or accessed with recovery software.

For illustrative purposes, the controller device 202 is described writing predetermined data onto the memory portion 306 after reading read data from that location, although it is understood that the controller device 202 may not performed the data protection write. For example, the controller device 202 can selectively write to a predetermined set of locations in the memory device 204 such that a portion of the memory device 204 may be protected but other portions does not necessarily have to be protected.

It has been discovered that the present invention provides data protection for the removable nonvolatile memory system by eliminating the data with writing a predetermined pattern after read access or a predetermined number of reads. The removable nonvolatile memory system provides a robust and reliable data protection by writing to the memory portion that has been read. The removable nonvolatile memory system also provides a low cost, low power and high performance data protection system without requiring complex encryption/decryption hardware or software.

Referring now to FIG. 6, therein is shown an illustrative view of the removable nonvolatile memory system 102 in a further addressing step. The illustrative view depicts the memory array 302 in the further addressing step by the controller device 202 through the address decoder 304. The address decoder 304 provides access to a further memory portion 602 in the memory array 302. The memory portion 306 contains the predetermined pattern thereby eliminating the previous data stored ensuring data protection for the previous data.

For illustrative purposes, the controller device 202 is shown writing the predetermined pattern to the memory portion 306 and reading the further memory portion 602, although it is understood that the controller device 202 may perform the data protection write differently. For example, the controller device 202 may read both the memory portion 306 and the further memory portion 602 before performing the data protection write to both the memory portion 306 and the further memory portion 602.

As another example, the controller device 202 may read a page of the memory array 302 including the memory portion 306 and the further memory portion 602 followed by the data protection write to the page in the memory array 302. This grouped reading and data protection writing can improve access performance of the removable nonvolatile memory system 102. Also, the grouped reading and data protection writing of the memory array 302 provide the controller device 202 an opportunity to verify the data without prematurely writing the predetermined pattern eliminating the data stored in the page. The grouped reading and verification can improve the bits needed for verification overhead. For example, error detection or error correction code can be used to cover a larger size of data in the memory array 302.

Referring now to FIG. 7, therein is shown a flow chart of a removable nonvolatile memory system 700 for operation of the removable nonvolatile memory system 102 in an embodiment of the present invention. The system 700 includes storing read data onto a memory portion of a memory device in a block 702; and accessing the memory portion including reading the read data from the memory portion, and writing predetermined data onto the memory portion after reading the memory portion in a block 704.

Yet other important aspects of the embodiments include that it valuably supports and services the historical trend of reducing costs, simplifying systems, and increasing performance.

These and other valuable aspects of the embodiments consequently further the state of the technology to at least the next level.

Thus, it has been discovered that the electronic system of the present invention furnishes important and heretofore unknown and unavailable solutions, capabilities, and functional aspects for improving reliability in systems. The resulting processes and configurations are straightforward, cost-effective, uncomplicated, highly versatile, and effective, can be implemented by adapting known technologies, and are thus readily suited for efficiently and economically manufacturing stackable integrated circuit package system.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A removable nonvolatile memory system comprising:
storing read data onto a memory portion of a memory device; and
accessing the memory portion including:
reading the read data from the memory portion, and
writing predetermined data onto the memory portion after reading the memory portion.

2. The system as claimed in claim 1 wherein writing the predetermined data onto the memory portion includes writing data different from the read data.

3. The system as claimed in claim 1 wherein reading the read data from the memory portion includes reading a row of the memory device.

4. The system as claimed in claim 1 wherein reading the read data from the memory portion includes reading a page of the memory device.

5. The system as claimed in claim 1 further comprising forming an electronic system with the memory device.

6. A removable nonvolatile memory system comprising:
storing read data onto a memory portion of a memory device;
reading the read data from the memory portion; and
writing predetermined data different from the read data onto the memory portion immediately after reading the memory portion.

7. The system as claimed in claim 6 wherein reading the read data from the memory portion includes reading the read data once from the memory portion.

8. The system as claimed in claim 6 further comprising:
reading a further memory portion of the memory device; and
wherein writing the predetermined data different from the read data onto the memory portion immediately after reading the memory portion includes:
writing the predetermined data to both the memory portion and the further memory portion.

9. The system as claimed in claim 6 further comprising verifying the read data from the memory portion before writing the predetermined data.

10. The system as claimed in claim 6 wherein writing the predetermined data different from the read data onto the memory portion immediately after reading the memory portion includes selectively not writing the predetermined data onto a further memory portion of the memory device.

11. A removable nonvolatile memory system comprising:
a memory portion of a memory device for storing read data; and
a controller device coupled to the memory device for accessing the memory portion including:
reading the read data from the memory portion, and
writing predetermined data onto the memory portion after reading the memory portion.

12. The system as claimed in claim 11 wherein the controller device includes a control block for writing the predetermined data different from the read data onto the memory portion.

13. The system as claimed in claim 11 wherein the memory portion includes a row of the memory device.

14. The system as claimed in claim 11 wherein the memory portion includes a page of the memory device.

15. The system as claimed in claim 11 further comprising an electronic system with the memory device.

16. The system as claimed in claim 11 wherein the controller device includes a control block for writing the predetermined data different from the read data onto the memory portion immediately after reading the memory portion.

17. The system as claimed in claim 16 wherein the controller device includes the control block for reading the read data once from the memory portion.

18. The system as claimed in claim 16 wherein the controller device includes the control block for reading a further memory portion of the memory device and writing the predetermined data to both the memory portion and the further memory portion.

19. The system as claimed in claim 16 wherein the controller device includes the control block for verifying the read data from the memory portion before writing the predetermined data.

20. The system as claimed in claim 16 wherein the controller device includes the control block for selectively not writing the predetermined data onto a further memory portion of the memory device.
